(19) United States
(12) Patent Application Publication
(10) Pub. No.: US 2026/0010696 A1
(43) Pub. Date: Jan. 8, 2026

(54) SYSTEM AND METHOD FOR GENERATING RECIPE RECOMMENDATIONS DURING LOGIC SYNTHESIS OPTIMIZATION OF ELECTRONIC CIRCUITS

(71) Applicant: Huawei Technologies Co., Ltd., Shenzhen (CN)

(72) Inventors: Raika Karimi, Toronto (CA); Faezeh Faez, Toronto (CA); Yingxue Zhang, Markham (CA); Mahdi Biparva, Toronto (CA)

(21) Appl. No.: 18/986,259

(22) Filed: Dec. 18, 2024

Related U.S. Application Data
(60) Provisional application No. 63/668,070, filed on Jul. 5, 2024.

(51) Int. Cl. G06F 30/327; G06F 30/337

(52) U.S. Cl. CPC G06F 30/327; G06F 30/337

(57) ABSTRACT

A method is performed by a trained recipe recommendation model. The method comprises loading a plurality of circuits into a circuit data loader; separately loading a plurality of recipes into a recipe data loader; and generating a recommended recipe for each circuit based on at least one quality of result determined during logic synthesis optimization.

### CROSS-REFERENCE TO RELATED APPLICATIONS

This application claims priority to U.S. Provisional Patent No. 63/668,070, filed Jul. 5, 2024, the entire contents of which are incorporated herein by reference.

### FIELD

The present application relates to electronic design automation and in particular to a system and method for generating recipe recommendations during logic synthesis optimization of electronic circuits.

### BACKGROUND

Electronic Design Automation (EDA) refers to a category of software tools for designing electronic systems such as for example integrated circuits (ICs) and printed circuit boards (PCBs). EDA tools automate various stages of the design process.

Logic synthesis optimization (LSO) is a critical phase in the EDA process. LSO involves transforming a high-level hardware description of a circuit into an optimized gate-level representation. This step is crucial for ensuring that the circuit meets specific design criteria such as for example performance, area and power consumption. The optimization phase seeks to refine the circuit by minimizing the number of logic gates and the complexity of interconnections while maximizing speed and reducing power usage. LSO utilizes various algorithms and heuristics to achieve a balance between these completing objectives, enabling a more efficient and effective design.

### SUMMARY

Accordingly, in one aspect there is provided a method performed by a recipe recommendation model comprising loading a plurality of circuits into a circuit data loader; separately loading a plurality of recipes into a recipe data loader; generating a recommended recipe for each circuit based on a quality of result determined during logic synthesis optimization.

In one or more embodiments, the method further comprises determining an intermediate quality of result during each iteration of the logic synthesis optimization.

In one or more embodiments, the method further comprises an auxiliary training task focused on predicting a quality of result trajectory based on the intermediate quality of results determined during each iteration of the logic synthesis optimization.

In one or more embodiments, the recipe recommendation model includes a graph encoder and a recipe encoder and the method further comprises training the graph encoder and the recipe encoder to predict intermediate quality of results based on a set of training data generated during previous logic synthesis optimizations.

In one or more embodiments the training includes self-supervised learning.

In one or more embodiments, the method comprises providing a plug-in to a software module associated with electronic design automation, the plug-in configured to perform the method in response to detection of a trigger condition.

In one or more embodiments, the trigger condition includes selection of an interface element requesting performance of the method.

In one or more embodiments, the quality of result includes at least one of performance, area, power consumption, yield and reliability.

In one or more embodiments, the method further comprises engaging a novel And-Inverter Graph (AIG) encoder to efficiently map each large-scale circuit to lower dimension embedding space.

In another aspect, embodiments of this disclosure provide a computer system comprising a processor, and a memory coupled to the processor and storing a trained recipe recommendation model that includes processor-executable instructions which, when executed by the processor, configure the processor to perform any of the methods disclosed herein.

In another aspect, embodiments of this disclosure provide a computer readable storage medium, comprising one or more instructions, wherein when the one or more instructions are run on a computer, the computer performs any of the methods disclosed herein.

In another aspect, embodiments of this disclosure provide a non-transitory computer-readable medium storing instruction the instructions causing a processor in a device to implement any of the methods disclosed herein.

In another aspect, embodiments of this disclosure provide a device configured to perform any of the methods disclosed herein.

In another aspect, embodiments of this disclosure provide a processor, configured to execute instructions to cause a device to perform any of the methods disclosed herein.

In another aspect, embodiments of this disclosure provide an integrated circuit configure to perform any of the methods disclosed herein.

According to one aspect of this disclosure, there is provided a module comprising: one or more circuits for performing any of the methods disclosed herein.

According to one aspect of this disclosure, there is provided an apparatus comprising: one or more processors functionally connected to one or more memories for performing any of the methods disclosed herein.

According to one aspect of this disclosure, there is provided an apparatus configured to perform any of the methods disclosed herein.

In some embodiments the apparatus comprises one or more units configured to perform the above-described method.

According to one aspect of this disclosure, there is provided one or more non-transitory, computer-readable storage media comprising computer-executable instructions, wherein the instructions, when executed, cause at least one processing unit, at least one processor, or at least one circuits to perform any of the methods disclosed herein.

According to one aspect of this disclosure, there is provided one or more computer-readable storage media storing a computer program, wherein, when the computer program is executed by an apparatus, the apparatus is enabled to implement any of the methods disclosed herein.

According to one aspect of this disclosure, there is provided a computer program product including one or more instructions, wherein, when the instructions are executed by an apparatus, the apparatus is enabled to implement any of the methods disclosed herein.

According to one aspect of this disclosure, there is provided a computer program, wherein, when the computer program is executed by a computer, an apparatus is enabled to implement any of the methods disclosed herein.

According to one aspect of this disclosure, there is provided a system comprising a node for performing any of the methods disclosed herein.

Other aspects and features of the present application will be understood by those of ordinary skill in the art from a review of the following description of examples in conjunction with the accompanying figures.

### BRIEF DESCRIPTION OF THE DRAWINGS

Reference will now be made, by way of example, to the accompanying drawings in which:

FIGS. 1 to 3 show simplified schematic diagrams of a system for generating recipe recommendations during logic synthesis optimization of electronic circuits in accordance with one or more exemplary embodiments;

FIG. 4 shows, in flowchart form, one example method of generating recipe recommendations during logic synthesis optimization of electronic circuits in accordance with one or more exemplary embodiments;

FIG. 5 shows, in flowchart form, one example method of providing a software plug-in for generating recipe recommendations during logic synthesis optimization of electronic circuits in accordance with one or more exemplary embodiments;

FIG. 6 is a graph showing memory usage v. inference time in accordance with one or more exemplary embodiments;

FIG. 7 shows a high-level diagram of an example computing device in accordance with one or more exemplary embodiments; and

FIG. 8 shows a simplified example of software components within the computing device in accordance with one or more exemplary embodiments.

Like reference numerals are used in the drawings to denote like elements and features.

### DETAILED DESCRIPTION

In the context of EDA, Quality of Results (QoR) refers to the measure of how well the output of an EDA process meets the intended design specifications and requirements. QoR encompasses various aspects of the final product such as for example performance, area, power consumption, yield, and reliability.

Performance includes the speed at which the circuit operates and may be measured in terms of maximum operating frequency or delay.

Area includes the amount of physical space on the chip that the design occupies, which may have implications for cost, power consumption, and the ability to fit more functions on a single chip.

Power consumption may include the efficiency of the design in terms of power usage, which may be critical for battery-operated devices and overall energy efficiency.

Yield may include the proportion of devices manufactured without defects, influencing the feasibility of the design.

Reliability may include an expected operational lifespan and failure rates of the device.

QoR is critical because it directly affects the commercial and practical viability of a semiconductor product. In the EDA process, tools and methodologies aim to optimize these aspects to meet the design targets set by the specifications.

In contemporary hardware design, the creation of hardware devices is facilitated by the abstraction provided by high-level logic gates. During the integrated circuit (IC) fabrication process, conceptual designs are translated into tangible layouts with the aid of EDA tools. The use of EDA tools enables designers to focus exclusively on the functional aspects of designs at a high-level by employing hardware description languages (HDL) such as for example Verilog™.

LSO involves transforming a high-level hardware description of a circuit into an optimized gate-level representation. In LSO, a sequence of optimization transformations (heuristics) are applied to logic-level circuit designs to optimize the QoR. Different recipes may be used where each recipe may include a specific combination of heuristics and/or optimization techniques. Each recipe may represent a unique approach to solving the optimization problem, combining different strategies in an attempt to achieve the best possible outcome.

LSO may be conceptualized as a task of representation to circumvent the extensive processes involved in evaluating the final QoR through the EDA pipeline. LSO is a regressive task in which a parametric mapping (ƒ_{θ}) from the input space, Graphs (X) and Recipes (R), to the output space, QoR (Y), is learned. More specifically:

$${f}_{θ} : X \times R \to Y$$

where X is the initial logic graph, R is the sequence of heuristics (Recipe), and Y is the Quality of Result (QoR).

A number of techniques and frameworks have been developed in attempts to optimize the QoR of circuits during logic synthesis.

For example, reinforcement learning-based frameworks have been developed to autonomously navigate the optimization space without human intervention, aiming to improve the QoR. The methodology involves defining the LSO problem as a reinforcement learning task, where an agent iteratively applies transformations to the circuit design and learns to optimize it through a reward-based system. This approach identifies optimal recipes by navigating the expanding search space. This methodology is often performed in an online manner, leading to significant latency issues due to the slow execution of EDA software within the process.

As another example, an algorithm has been developed that adapts modern Bayesian optimization to navigate the space of synthesis operations. The algorithm does not require human intervention and utilizes Gaussian process kernels and trust-region constrained acquisitions to balance exploration and exploitation. The algorithm recommends a common recipe for all circuits.

At least some prior techniques input logic-level circuit designs in And-Inverter Graph (AIG) format, capitalizing on the inductive bias inherent in the Directed Acyclic Graph (DAG) structure whose nodes are partially ordered. Some prior techniques are dedicated to injecting the inductive bias of DAGs into message-passing graph encoders or graph transformers to enhance expressiveness. The present application builds on top of these concepts by generating graph-level representations that are well-suited for AIGs.

At least some prior techniques experience overfitting due to a limited number of publicly available circuits used during training, resulting in a lack of generalization, especially when tested on unseen circuits that differ in size and characteristics from the training circuits. Additionally, at least some prior techniques struggle with imbalanced input samples across different modalities as there are typically more recipes available than AIGs. This disparity may lead to prominent overfitting, particularly due to the low expressiveness of graph encoders.

At least some prior techniques utilize self-supervised learning to address the scarcity of data, offering an alternative to costly data augmentation methods, and to address issues of expressiveness in various downstream tasks related to LSO.

At least some prior techniques involve pre-training the circuit encoder component in advance, followed by fine-tuning it on specific downstream tasks. Inspired by predictive SSL, the present application predicts intermediate QoRs during LSO. The training mechanism of the present application provides a stronger supervisory signal during training, enhancing the learning process.

Another drawback of at least some prior techniques is that the encoder used for encoding the recipe lacks information from the input graphs, leading to an information bottleneck. The bottleneck occurs particularly when graph embeddings and recipe embeddings are merged using standard concatenation techniques. The present application includes a decoder-only transformer model for training, employing a joint loss function. As a result, the model defined by the present application contextualizes the embeddings of heuristics using AIG embeddings through a cross-attention module facilitating a more effective integration of information.

At least some prior techniques are inefficient in terms of loading circuits. At least some prior techniques perform QoR prediction rather than recommending optimal recipes without exhaustive search. Further, at least some prior techniques rely solely on final QoR for supervision during training, and do not predict intermediate signals such as intermediate QoRs during inference.

The present application provides a personalized recipe recommendation model. As will be described in more detail, given the circuit and recipe candidates, the model of the present application is configured to output a recommendation that includes a recommended recipe for a corresponding circuit. The present application increases efficiency in terms of both inference and training.

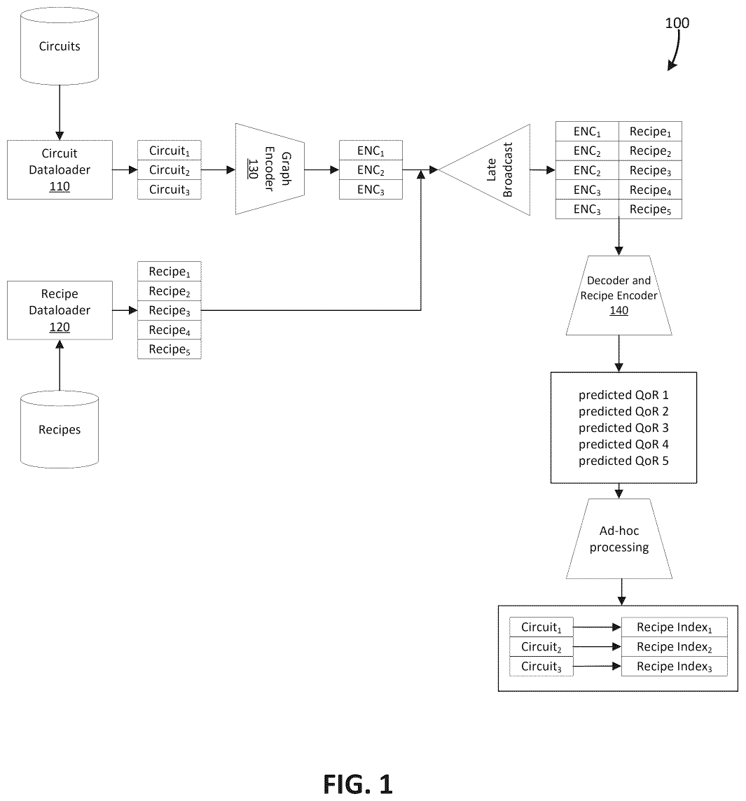

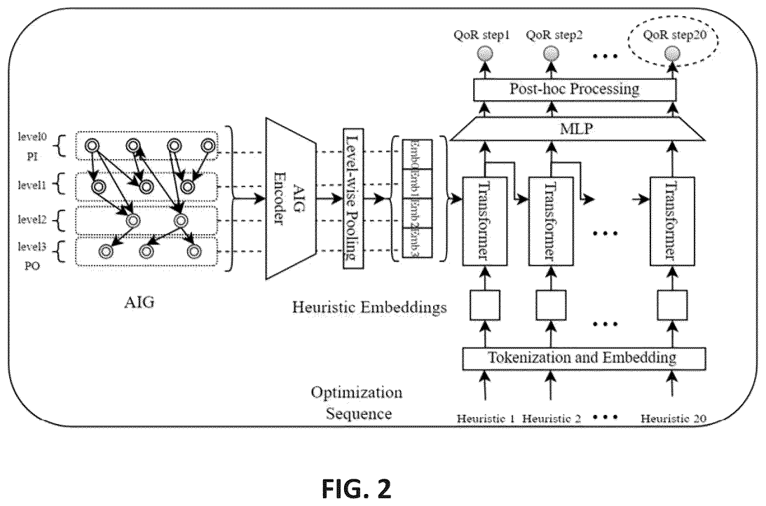

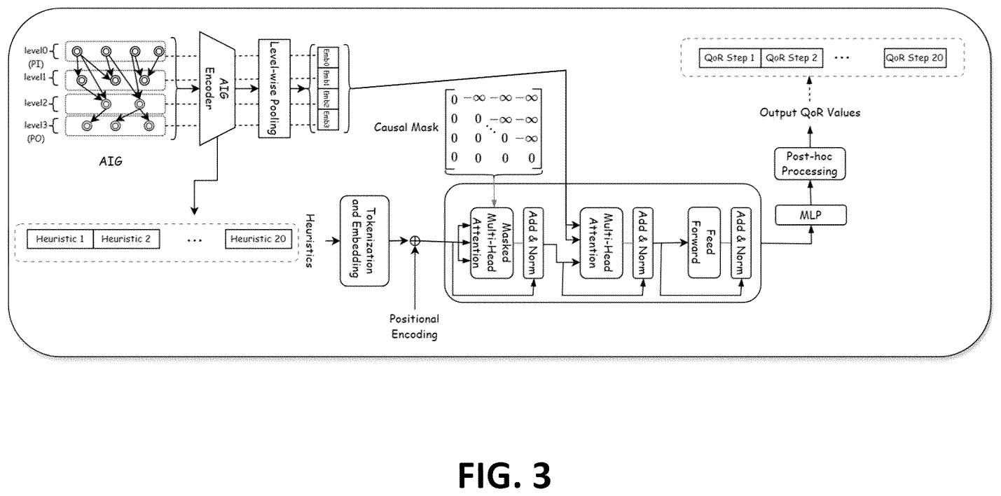

FIGS. 1 to 3 illustrate solutions provided by the present application. As shown in FIG. 1, a system 100 includes a circuit data loader 110, a recipe data loader 120, a graph encoder 130, a decoder and recipe encoder 140. The circuit data loader 110 loads circuits in batches or mini-batches and provides them to the graph encoder 130. The recipe data loader separately loads recipes in batches or mini-batches. The decoder and recipe encoder 140 may generate predicted quality of results (QoR). As will be described in more detail, the system 100 may be trained to generate recipe recommendations during logic synthesis optimization of electronic circuits.

As shown in FIG. 1, circuits are loaded into the circuit data loader 110 and the recipes are loaded into the recipe data loader 120. In this manner, during both training and inference the circuits are simultaneously processed in a batch. This avoids loading and encoding repetitive graphs multiple times at each batch and this decreases the inference time as well as the training time. The pipeline is configured to generate a recommended recipe for each circuit rather than finding a recommended recipe for all circuits. Put another way, the pipeline is configured to generate a personalized recipe for each circuit.

The circuits may include logic-level designs. The logic-level designs are stored and are converted into And-Inverter Graph (AIG) format. The AIG format is a type of Directed Acyclic Graph (DAG) that includes nodes representing a 2-input AND function and edges that signify either NOT or buffer functions. The structure simplifies the representation and manipulation of Boolean functions facilitating various logic synthesis and optimization tasks.

The input AIGs are transformed into attributed directed acyclic graphs (DAGs) G=(V, E, Xᵥ), comprising N nodes and E=|E| directed edges. Node features Xᵥ are categorized into two types: features that represent the classification of nodes (input, output, or intermediate) and the count of inverted predecessors for each gate, respectively. A set of Recipes is denoted as A={r₁, r₂, r₃, . . . , r_{R}}, which comprises R Recipes, each containing M sequentially ordered heuristics selected from a set of C available Heuristics, F={F₁, F₂, . . . , F_{C}}.

In the EDA workflow, the present application optimizes logic-level circuits modeled by AIG graphs G. After applying the ith heuristic sequentially and optimizing the logic-level representation, the technology mapping may be applied to map the optimized version to the QoR after each step shown by

$$Q o {R}_{G T}^{k} .$$

The final QoR after M^{th} heuristics, named QoR_{GT}, is the ground truth of the model that the present application is expected to predict given the input AIGs and Recipes during inference mode.

The model is trained to predict the trajectory of QoR evolution. To this end, the model predicts all M intermediate QoRs in a causal manner in such a way that to predict the ith QoR, all heuristics before the ith step, (r₁, r₂, . . . , rᵢ) are input to the model. This predictive SSL task by itself is aligned with architecture of the transformer decoder to help the model benefit from extra data within the intermediate steps.

The QoR prediction task aims to find the learnable function F_{prediction} that maps a pair of Recipe and AIG graph, (G, rᵢ) to a numerical value QoR_{Prediction} which is a prediction of final ground truth QoR. More specifically, the task is as follows:

$$Q o {R}_{p rediction} = {F}_{p rediction} ( 𝒢 , {r}_{i} )$$

The final loss is determined as a Mean Squared Error using the following:

$$loss = {\sum }_{k = 1}^{M} MSE ( {QoR}_{p rediction}^{k} , {QoR}_{G T}^{k} )$$

In the AIG segment, the model employs a graph encoder 130 ƒ_{θ} based on the following formula:

$$H = {f}_{θ} ( 𝒢 )$$

where H={h₁, h₂, h₃, . . . , h_{N}} and represents the set of node embeddings and hᵢ∈ [symbol] is node embedding with a dimension size of dh. In this embodiment, the model utilizes a Graph Convolutional Neural Network (GCN) that utilizes a node embedding approach to encode the AIGs.

Although the GCNs can encode graphs properly, they are unable to particularly incorporate the inductive bias of DAGs. To benefit from this bias to improve the graph representation learner, the present application utilizes a unique pooling mechanism called level-wise pooling. Level-wise pooling includes calculating the depth of the nodes through the function depth(v) due to the partial order intrinsic of the DAG. The set of node Embeddings are partitioned based on the depth of each node. The AIG graph is then represented as a sequence for the decoder layer. The sequence is derived according to the combination of mean and max poolings within each level.

Each Recipe, rᵢ=(ƒ₁, ƒ₂, . . . , ƒ_{M}) where f_i∈F, is tokenized using a one-hot vector with the length of C. A lookup table is utilized to generate learned embeddings to convert the input tokens to vectors with the length of 2×dh.

Once the Recipes are embedded and the AIG is converted to a sequence, the present application utilizes a sequence to sequence alignment module that uses only a transformer decoder module having decoder architecture to fuse the AIG sequence with heuristics' embeddings. In other words, the transformer module maps AIG sequence and heuristics' embeddings to the trajectory of QoRs in a causal or autoregressive manner.

In the present application, the decoder architecture utilizes positional encoding. For example, positional encoding may be added to the sequence of heuristics embeddings element-wise.

The decoder architecture may include a masked multi-head self-attention module that contextualizes each input sequence fed to the transformer using its own sequence embeddings. The causal matrix is an upper triangular matrix and is applied to the sequence of heuristics. This structure imposes causality and ensures that each position in the sequence can only attend to itself and previous positions and not to any future positions.

The decoder architecture may include a cross-attention module that computes attention weights between an element of the AIG sequence and contextualized heuristic embeddings. A Feed-Forward layer (FFN) with Relu function may be applied element-wise to the sequence.

The decoder architecture may include a normalization layer such that each sub-layer may include a residual connection followed by layer normalization.

The decoder may include a regressor module such that once the embeddings for each QoR has been generated sequentially, an MLP module may be used to map the embeddings to the final QoR.

Once the model is derived to predict QoR accurately, the QoR prediction model may be deployed to efficiently process AIGs and generate recommendations for a specific recipe for a specific circuit.

In one or more embodiments, the present application may provide an online recipe search setting which may be personalized for a given circuit. Put another way, the pipeline may generate recommendations for sequence optimizers for each circuit.

As mentioned, the present application may load circuits and recipes separately into the pipeline and in this manner the processing of repetitive circuits for multiple recipes is avoided. The pipeline speeds up processing during both training and inference and reduces memory consumption.

In one or more embodiments, the present application proposes a transformer-based architecture that leverages intermediate QoR for optimizers by predicting the trajectory of QoRs. The QoR intermediate trajectory prediction enables the model to grasp the evolution trajectory. This capability fosters an inductive bias and as such the model is able to acquire insights into sequency behaviors thereby enhancing the learning or training process.

The present application utilizes an auxiliary predictive task that is defined and utilized as a model regularizer. Specifically, the present application predicts the trajectory of QoR after each optimization step during the LSO. By predicting the trajectory of the QoR after each optimization step, an auxiliary predictive SSL task may be designed to predict intermediate QoR for joint training. The present application utilizes a causal transformer that may include a decoder-only transformer model that causally predicts QoR based on the recipes and the AIGs. Further, the present application utilizes contextualized fusion to fuse embeddings of AIGs and recipes using a cross-attention module. This approach contextualizes the embeddings of recipes with AIGs, enabling the model to learn which parts of the graph each heuristic attends to.

The causal transformer described herein may include a specific type of transformer model configured to handle sequences in a manner where the output at any time step is dependent only on previous time steps. The causal transformer is autoregressive where each output may be generated sequentially and depends only on previous outputs. In this manner, the causal transformer ensures that each position in the output sequence is predicted based on all preceding positions and no future positions, thereby maintaining a causal one-directional flow of information.

Self-supervised learning (SSL) described herein may include a type of machine learning where the system learns to understand and work with data without explicit external labels provided by humans. Rather, the system generates its own labels from the data itself and this may be done by creating a predictive task from the data's inherent structure. The use of self-supervised learning described herein reduces dependency on large labeled datasets which are often costly and time-consuming to product. Further, the use of self-supervised learning enables the system to generalize better to new tasks because the system is able to learn from mode robust features of data without relying on specific human defined labels. Further, the use of self-supervised learning accelerates the initial training phase by utilizing unlabeled data and enhances the model's ability to learn new tasks quickly with minimal additional data.

In manners described herein, the present application outputs a recommended personalized recipe for a given circuit from all candidate recipes, providing a more efficient alternative to predicting QoR or conducting slow online recipe searches. The present application prevents loading and encoding of large, redundant graphs in each batch, reducing both inference and training times. Further, the present application adds an auxiliary loss during the training phase. The graph encoder and the recipe encoder are trained to predict intermediate QoR after each optimization step. The present application trains and infers the decoder and transformer in a one-shot causal decoding manner.

In one or more embodiments, the present application may be provided as a plug-in or extension to an existing EDA software application. For example, the plug-in may be provided within the software application and may cause the software application to present a selectable interface element to utilize the personalized recipe recommendation model to optimize logic-level designs in manners described herein.

In one or more embodiments, the present application may be provided as an artificial intelligence assistance tool which may predict effective recipes for specific circuit designs thereby enabling logic circuit designers to swiftly refine their layouts and proceed to manufacturing phases.

In manners described herein, the personalized recipe recommendation model expedites the process of logic-level design optimization while using less computing resources such as for example memory. The present application may increase the feasibility of products for deployment in scenarios where customers have limited hardware resources.

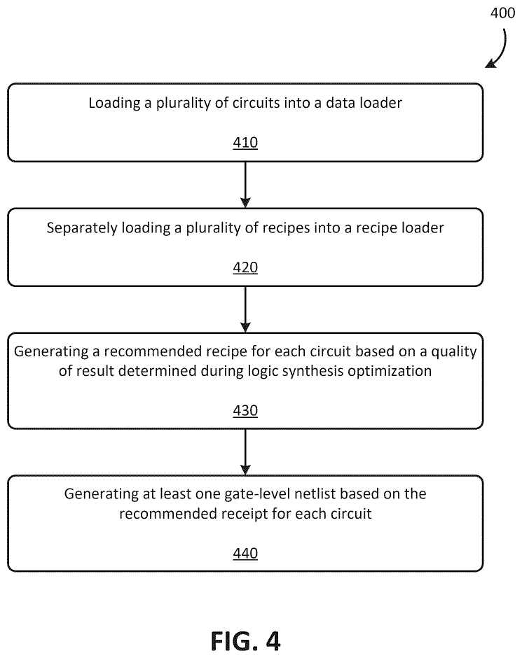

Reference is now made to FIG. 4, which shows, in flowchart form, one example method 400 of generating recipe recommendations during logic synthesis optimization of electronic circuits. The method 400 may be implemented in software executed by one or more processing units of a computing device.

The method 400 includes loading a plurality of circuits into a circuit data loader (step 410).

In this embodiment, the circuits may include circuits that are to be included in one or more circuit designs generated or created using logic synthesis optimization.

The circuits may include logic-level designs. As mentioned, the logic-level designs are stored and are converted into And-Inverter Graph (AIG) format. The AIG format is a type of Directed Acyclic Graph (DAG) that includes nodes representing a 2-input AND function and edges that signify either NOT or buffer functions. The structure simplifies the representation and manipulation of Boolean functions facilitating various logic synthesis and optimization tasks.

The input AIGs may be transformed into attributed directed acyclic graphs (DAGs) G=(V, E, Xᵥ), comprising N nodes and E=|E| directed edges. Node features X, are categorized into two types: features that represent the classification of nodes (input, output, or intermediate) and the count of inverted predecessors for each gate, respectively. A set of Recipes is denoted as A={r₁, r₂, r₃, . . . , r_{R}}, which comprises R Recipes, each containing M sequentially ordered heuristics selected from a set of C available Heuristics, F={F₁, F₂, . . . , F_{C}}.

During both training and inference, the circuits are loaded and processed in a batch. By batch processing the circuits during training and inference, the overall process is more efficient and computation resources are leveraged more effectively.

The method 400 includes separately loading a plurality of recipes into a recipe data loader (step 420).

The recipes are loaded into the recipe data loader and this is done separately from the loading of the circuits into the circuit data loader. As mentioned, the circuits are loaded into a circuit data loader and the recipes are loaded into a recipe data loader. In this manner, during both training and inference the circuits are simultaneously processed in a batch. This avoids loading and encoding repetitive graphs multiple times at each batch and this decreases the inference time as well as the training time.

In one or more embodiments, each Recipe, rᵢ=(ƒ₁, ƒ₂, . . . , ƒ_{M}) where f_i∈F, may be tokenized using a one-hot vector with the length of C. A lookup table may be utilized to generate learned embeddings to convert the input tokens to vectors with the length of 2×dh.

The method 400 includes generating a recommended recipe for each circuit based on a quality of result determined during logic synthesis optimization (step 430).

As mentioned, rather than finding a recommended recipe for all circuits, the model is configured to generate a personalized recipe for each circuit.

In one or more embodiments, the logic synthesis optimization may be iterative. In these embodiments, an intermediate quality of result may be determined during or at each iteration of the logic synthesis optimization. The quality of result may include at least one of performance, area, power consumption, yield and reliability.

As outlined above, the recipe recommendation model may include a graph encoder and a recipe encoder that may be trained using training data generated during previous logic synthesis optimizations. Specifically, the training data may include quality of results data that may be used to train the graph encoder and/or the recipe encoder to predict intermediate quality of results during logic synthesis optimizations. The training may include self-supervised learning (SSL) where the model may be trained on training data without the requirement of human-provided labels. The graph encoder and/or the recipe encoder may be configured to process input data and transform it into a more useful representation that can be used to make predictions such as to predict quality of results.

As mentioned, in one or more embodiments, as an auxiliary task helping the model during training, the model may be trained to predict the trajectory of QoR evolution. To this end, the model predicts all M intermediate QoRs in a causal manner in such a way that to predict the ith QoR, all heuristics before the ith step, (r₁, r₂, . . . , rᵢ) are input to the model. This predictive SSL task by itself is aligned with architecture of the transformer decoder to help the model benefit from extra data within the intermediate steps.

Further, as mentioned, the QoR prediction task aims to find the learnable function F_{prediction} that maps a pair of Recipe and AIG graph, (G, rᵢ) to a numerical value QoR_{Prediction} which is a prediction of final ground truth QoR. More specifically, the task is as follows:

$$Q o {R}_{p rediction} = {F}_{p rediction} ( 𝒢 , {r}_{i} )$$

The final loss is determined as a Mean Squared Error using the following:

$$loss = {\sum }_{k = 1}^{M} M S E ( Q o {R}_{p rediction}^{k} , Qo {R}_{G T}^{k} )$$

In the AIG segment, the model employs a graph encoder ƒ_{θ} based on the following formula:

$$H = {f}_{θ} ( 𝒢 )$$

where H={h₁, h₂, h₃, . . . , h_{N}} and represents the set of node embeddings and hᵢ∈ [symbol] is node embedding with a dimension size of dh. In this embodiment, the model utilizes a Graph Convolutional Neural Network (GCN) that utilizes a node embedding approach to encode the AIGs.

As outlined above, level-wise pooling may be utilized that includes calculating the depth of the nodes through the function depth (v) due to the partial order intrinsic of the DAG. The set of node Embeddings are partitioned based on the depth of each node. The AIG graph is then represented as a sequence for the decoder layer. The sequence is derived according to the combination of mean and max poolings within each level.

Once the Recipes are embedded and the AIG is converted to a sequence, a sequence to sequence alignment module may be used that uses only a transformer decoder module to fuse the AIG sequence with heuristics' embeddings. In other words, the transformer module maps AIG sequence and heuristics' embeddings to the trajectory of QoRs in a causal or autoregressive manner.

The decoder architecture may utilize positional encoding. For example, positional encoding may be added to the sequence of heuristics embeddings element-wise.

The decoder architecture may include a masked multi-head self-attention module that contextualizes each input sequence fed to the transformer using its own sequence embeddings. The causal matrix is an upper triangular matrix and is applied to the sequence of heuristics.

The decoder architecture may include a cross-attention module that computes attention weights between an element of the AIG sequence and contextualized heuristic embeddings. A Feed-Forward layer (FFN) with Relu function may be applied element-wise to the sequence.

The decoder architecture may include a normalization layer such that each sub-layer may include a residual connection followed by layer normalization.

The decoder may include a regressor module such that once the embeddings for each QoR has been generated sequentially, an MLP module may be used to map the embeddings to the final QoR.

Once the model is derived to predict QoR accurately, the QoR prediction model is configured to generate recommendations for a specific recipe for a specific circuit.

In one or more embodiments, the intermediate quality of result for each iteration may be used to generate a quality of result trajectory prediction. For example, the intermediate quality of results may be mapped or graphed to generate the quality of result trajectory prediction.

The method 400 includes generating at least one gate-level netlist based on the recommended recipe for each circuit (step 440).

The netlist may include a text-based representation that lists all the logic gates and their connections. The netlist may then be used to create a layout for one or more integrated circuits (ICs) and/or may be used to generate a schematic.

The netlist may additionally or alternatively be used to simulate the circuit's behavior prior to moving to physical design. This may help verify that the optimized circuit performs the required functions correctly. The design may be tested using one or more software simulation tools such as for example ModelSim™ or Xilinx™ Vivado™.

In manners described herein, logic graphs may be encoded once and reused multiple times. This avoids encoding duplicate logic graphs. Put another way, by encoding logic graphs once and reusing the encoding for every recipe in the list of recipes that requires that logic graph, computer efficiency is increased as unnecessary recomputation is avoided.

As mentioned, in one or more embodiments, the present application may be provided as a plug-in or extension to an existing EDA software application. For example, the plug-in may be provided within the software application and may cause the software application to present a selectable interface element to utilize the personalized recipe recommendation model to optimize logic-level designs in manners described herein.

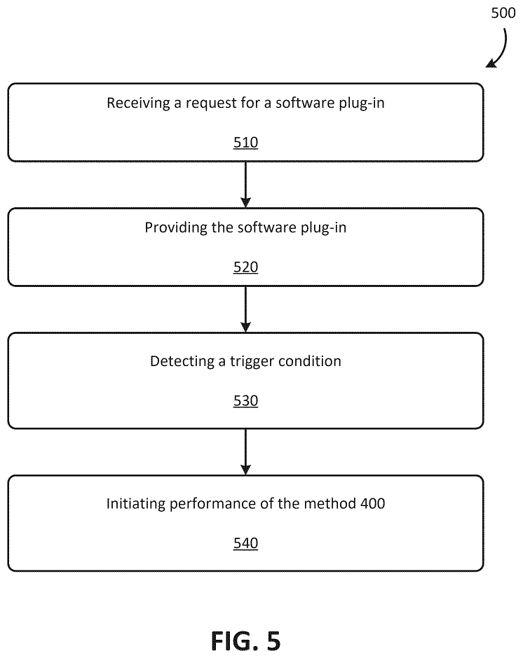

Reference is now made to FIG. 5, which shows, in flowchart form, one example method 500 of providing a software plug-in for generating recipe recommendations during logic synthesis optimization of electronic circuits. The method 500 may be implemented in software executed by one or more processing units of a computing device.

The method 500 includes receiving a request for a software plug-in (step 510).

In one or more embodiments, a user of a computing device executing one or more EDA software tools may submit a request to download or otherwise obtain the software plug-in. The request may be submitted within an EDA software tool or may be submitted online such as for example on a particular website.

The method 500 includes providing the software plug-in (step 520).

Responsive to receiving the request, the software plug-in may be provided or otherwise downloaded onto the computing device executing the one or more EDA software tools. Once downloaded, the software plug-in may be accessible within the one or more EDA software tools. For example, a toolbar of an EDA software tool may be updated to indicate that the software plug-in is available and may include a selectable option to activate or engage the software plug-in.

The method 500 includes detecting a trigger condition (step 530).

The trigger condition may include selection of the selectable option. For example, within a particular EDA software tool the user may select the selectable option to activate or engage the software plug-in.

The method 500 includes initiating performance of the method 400 (step 540).

In response to detection of the trigger condition, operations may be performed to initiate performance of the method 400 to generate recipe recommendations during logic synthesis optimization of electronic circuits that may be created within the EDA software.

The pipeline described herein requires less memory and computational cost compared to baseline such as for example OpenABC-D Baseline. Metrics such as for example inference/training time, memory usage, Mean Absolute Percentage Error (MAPE) may be used. Tables 1 and 2 show measured metrics comparing the pipeline described herein to OpenABC-D Baseline.

TABLE 1
MAPE % of OpenABC-D and QoR trajectory prediction

| Performance on OpenABC-D Dataset | MAPE (%) |
|---|---|
| OpenABC-D Baseline | 23.58 |
| QoR trajectory prediction (described herein) | 22.75 |

TABLE 2
Comparing OpenABC-D Pipeline with
the pipeline described herein

| Time per Epoch | Training | Inference | Memory |
|---|---|---|---|
| OpenABC-D Dataset | time (seconds) | time (seconds) | Usage (MB) |
| OpenABC-D pipeline | 69.680 ± 0.640 | 45.491 ± 0.135 | 34.41 |
| Pipeline described | 20.460 ± 0.603 | 7.542 ± 0.018 | 7.582 |
| herein | | | |

As can be seen, the pipeline described herein has a lower MAPE %, a faster training time, a faster inference time, and requires less memory.

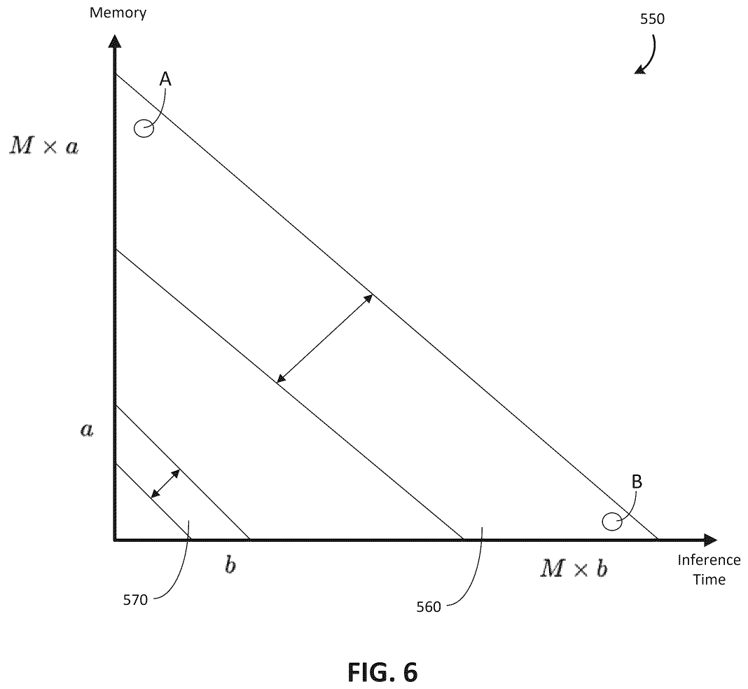

The relationship between memory usage and inference time may be analyzed to show further advantages provided by the pipeline described herein. An example graph showing memory usage v. inference time is shown in FIG. 6, where decision boundary 560 represents baseline and the decision boundary 570 represents the pipeline described herein. Node A and Node B are also shown. As the number of processed elements increases, memory demand rises, thereby reducing inference times under certain conditions (Node A). In contrast, reduced batch sizes lead to longer inference times but lower memory consumption (Node B).

In one or more embodiments described herein, a recipe may include a structures sequence of steps that leverages a combination of heuristics to guide decision-making and achieve design objections such as minimizing area, power, or timing. A recipe may encapsulate these heuristics along with constraints, tool settings, and iteration strategies to efficiently explore and optimize the solution space.

In one or more embodiments described herein, a recipe recommendation may include a recommended combination of heuristics, constraints, and tool settings tailored to a specific design goal such as improving timing, reducing power, or balancing area and performance.

In one or more embodiments described herein, a trained recipe recommendation model may include one or more artificial intelligence models trained to generate recipe recommendations in accordance with the one or more embodiments described herein.

In one or more embodiments described herein, QoR trajectory prediction may include an auxiliary predictive task to predict intermediate QoR during each iteration performed in accordance with one or more embodiments described herein. The QoR trajectory prediction may represent the evolution or progression of the QoR over the optimization process.

In one or more embodiments described herein, the intermediate QoR may include a QoR determined during each iteration performed in accordance with one or more embodiments described herein. The intermediate QoR may include QoR measured or predicted at specific points during the synthesis process before reaching the final optimized design.

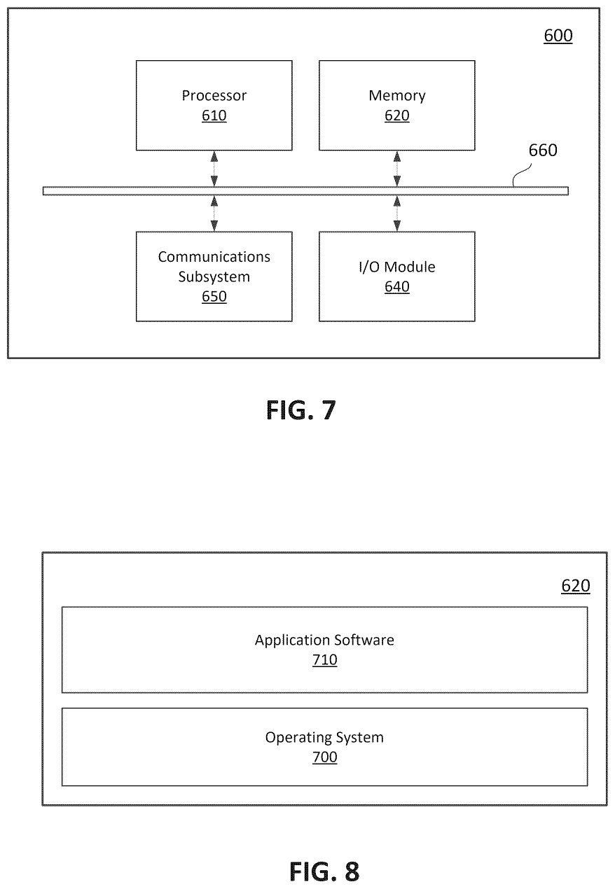

Reference will now be made to FIG. 7, which shows a high-level diagram of an example computing device 600. The example computing device 600 includes a variety of modules. For example, the example computing device 600 may include a processor 610, a memory 620, an I/O module 640, and a communications module 650. As illustrated, the foregoing example modules of the example computing device 600 are in communication over a bus 660.

The processor 610 is a hardware processor. The processor 610 may, for example, be one or more ARM, Intel x86, PowerPC processors, or the like.

The memory 620 allows data to be stored and retrieved. The memory 620 may include, for example, random access memory, read-only memory, and persistent storage. Persistent storage may be, for example, flash memory, a solid-state drive or the like. Read-only memory and persistent storage are a computer-readable medium. A computer-readable medium may be organized using a file system such as may be administered by an operating system governing overall operation of the example computing device 600.

The I/O module 640 allows the example computing device 600 to receive input signals and to transmit output signal. Input signals may, for example, correspond to input received from a user. Some output signals may, for example, allow provision of output to a user. The I/O module 640 may serve to interconnect the example computing device 600 with one or more input devices. Input devices may, for example, include one or more of a touchscreen input, keyboard, trackball or the like. The I/O module 640 may serve to interconnect the example computing device 600 with one or more output devices. Output devices may include, for example, one or more display screens such as, for example, a liquid crystal display (LCD), a touchscreen display. Additionally, or alternatively, output devices may include devices other than screens such as, for example, a speaker, indicator lamps (such as, for example, light-emitting diodes (LEDs)), and printers.

The communications module 650 allows the example computing device 600 to communicate with other electronic devices and/or various communications networks. For example, the communications module 650 may allow the example computing device 600 to send or receive communications signals. As an example, the communication module 650 may include a network connection, data port, or the like. Communications signals may be sent or received according to one or more protocols or according to one or more standards. For example, the communications module 650 may allow the example computing device 600 to communicate via a cellular data network, such as for example, according to one or more standards such as, for example, Global System for Mobile Communications (GSM), Code Division Multiple Access (CDMA), Evolution Data Optimized (EVDO), Long-term Evolution (LTE), 5G, 6G, or the like. Additionally, or alternatively, the communications module 650 may allow the example computing device 600 to communicate using near-field communication (NFC), via Wi-Fi™, via the Ethernet family of network protocols, using Bluetooth™ or via some combination of one or more networks or protocols. In some embodiments, all or a portion of the communications module 650 may be integrated into a component of the example computing device 600. In some examples, the communications module may be integrated into a communications chipset.

Software instructions are executed by the processor 610 from a computer-readable medium. For example, software may be loaded into random-access memory from persistent storage within memory 620. Additionally, or alternatively, instructions may be executed by the processor 610 directly from read-only memory of the memory 620.

FIG. 8 depicts a simplified organization of software components stored in memory 620 of the example computing device 600. As illustrated, these software components include, at least, application software 710 and an operating system 700.

The application software 710 adapts the example computing device 600, in combination with the operating system 700, to operate as a device performing a particular function. While a single application software 710 is illustrated in FIG. 8, in operation, the memory 620 may include more than one application software and different application software may perform different operations.

The operating system 700 is software. The operating system 700 allows the application software 710 to access the processor 610, the memory 620, the I/O module 640, and the communications module 650. The operating system 700 may, for example, be iOS™, Android™, Linux™, Microsoft Windows™, or the like.

The application software 710 and/or operating system 700 may, when executed, cause the processor 610 to carry out operations to implement at least some portion of one or more of the methods described herein.

The systems and methods disclosed herein may comprise suitable modules and/or circuitries for executing various procedures.

As those skilled in the art understand, a “module” is a term of explanation referring to a hardware structure such as a circuitry implemented using technologies such as electrical and/or optical technologies (and with more specific examples of semiconductors) for performing defined operations or processing. A “module” may alternatively refer to the combination of a hardware structure and a software structure, wherein the hardware structure may be implemented using technologies such as electrical and/or optical technologies (and with more specific examples of semiconductors) in a general manner for performing defined operations or processing according to the software structure in the form of a set of instructions stored in one or more non-transitory, computer-readable storage devices or media.

A module may be a part of a device, an apparatus, a system, and/or the like, wherein the module may be coupled to or integrated with other parts of the device, apparatus, or system such that the combination thereof forms the device, apparatus, or system. Alternatively, the module may be implemented as a standalone device or apparatus.

The module usually executes a procedure for performing a method. Herein, a procedure has a general meaning equivalent to that of a method. More specifically, a procedure is a defined method implemented using hardware components for processing data. A procedure may comprise or use one or more functions for processing data as designed. Herein, a function is a defined sub-procedure or sub-method for computing, calculating, or otherwise processing input data in a defined manner and generating or otherwise producing output data.

As those skilled in the art will appreciate, a procedure may be implemented as one or more software and/or firmware programs having necessary computer-executable code or instructions and stored in one or more non-transitory computer-readable storage devices or media which may be any volatile and/or non-volatile, non-removable or removable storage devices such as RAM, ROM, EEPROM, solid-state memory devices, hard disks, CDs, DVDs, flash memory devices, and/or the like. A module may read the computer-executable code from the storage devices and execute the computer-executable code to perform the procedure.

Alternatively, a procedure may be implemented as one or more hardware structures having necessary electrical and/or optical components, circuits, logic gates, integrated circuit (IC) chips, and/or the like.

Herein, use of language such as “at least one of X, Y, and Z,” “at least one of X, Y, or Z,” “at least one or more of X, Y, and Z,” “at least one or more of X, Y, and/or Z,” or “at least one of X, Y, and/or Z,” is intended to be inclusive of both a single item (e.g., just X, or just Y, or just Z) and multiple items (e.g., {X and Y}, {X and Z}, {Y and Z}, or {X, Y, and Z}). The phrase “at least one of” and similar phrases are not intended to convey a requirement that each possible item must be present, although each possible item may be present.

In some embodiments, the methods disclosed herein may be implemented as computer-executable instructions stored in one or more non-transitory computer-readable storage devices (in the form of software, firmware, or a combination thereof) such that, the instructions, when executed, may cause one or more physical components such as one or more circuits to perform the methods disclosed herein.

For example, in some embodiments, an apparatus comprising one or more processors functionally connected to one or more non-transitory computer-readable storage devices or media may be used to perform the methods disclosed herein, wherein the one or more non-transitory computer-readable storage devices or media store the computer-executable instructions of the methods disclosed herein, and the one or more processors may read the computer-executable instructions from the one or more non-transitory computer-readable storage devices or media, and executes the instructions to perform the methods disclosed herein.

In some embodiments, an apparatus may not have any processors or computer-readable storage devices or media. Rather, the apparatus may comprise any other suitable physical or virtual components for implementing the methods disclosed herein.

In some embodiments, the computer-executable instructions that implement the methods disclosed herein may be one or more computer programs, one or more program products, or a combination thereof.

In some embodiments, the methods disclosed herein may be implemented as one or more circuits, one or more components, one or more units, one or more modules, one or more integrated-circuit (IC) chips, one or more chipsets, one or more devices, one or more apparatuses, one or more systems, and/or the like.

The one or more circuits, one or more components, one or more units, one or more modules, one or more IC chips, one or more chipsets, one or more devices, one or more apparatuses, or one or more systems may be physical, virtual, or a combination thereof. Herein, the term “virtual” (such as a “virtual apparatus”) refers to a circuit, component, unit, module, chipset, device, apparatus, system, or the like that is simulated or emulated or otherwise formed using suitable software or firmware such that it appears as if it is “real” or physical).

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiment may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Those skilled in the art will appreciate that the above-described embodiments and/or features thereof may be customized, separated, and/or combined as needed or desired. Moreover, although embodiments have been described above with reference to the accompanying drawings, those of skill in the art will appreciate that variations and modifications may be made without departing from the scope thereof as defined by the appended claims.

1. A method performed by a trained recipe recommendation model comprising:
loading a plurality of circuits into a circuit data loader;
separately loading a plurality of recipes into a recipe data loader; and
generating a recommended recipe for each circuit based on at least one quality of result determined during logic synthesis optimization.

2. The method of claim 1, further comprising:
determining an intermediate quality of result during each iteration of the logic synthesis optimization.

3. The method of claim 2, further comprising:
generating a quality of result trajectory prediction based on the intermediate quality of results determined during each iteration of the logic synthesis optimization.

4. The method of claim 1, wherein the recipe recommendation model includes a graph encoder and a recipe encoder and the method further comprises:
training the graph encoder and the recipe encoder to predict intermediate quality of results based on a set of training data generated during previous logic synthesis optimizations.

5. The method of claim 4, wherein the training includes self-supervised learning.

6. The method of claim 1, further comprising:
providing a plug-in to a software module associated with electronic design automation, the plug-in configured to perform the method in response to detection of a trigger condition.

7. The method of claim 6, wherein the trigger condition includes selection of an interface element requesting performance of the method.

8. The method of claim 1, wherein the quality of result includes at least one of performance, area, power consumption, yield and reliability.

9. The method of claim 1, further comprising:
engaging an And-Inverter Graph (AIG) encoder to map each large-scale circuit to lower dimension embedding space.

10. A computer system comprising:
a processor; and
a memory coupled to the processor and storing a trained recipe recommendation model that includes processor-executable instructions which, when executed by the processor, configure the processor to:
load a plurality of circuits into a circuit data loader;
separately load a plurality of recipes into a recipe data loader; and
generate a recommended recipe for each circuit based on at least one quality of result determined during logic synthesis optimization.

11. The computer system of claim 10, wherein the processor-executable instructions, when executed by the processor, further configure the processor to:
determine an intermediate quality of result during each iteration of the logic synthesis optimization.

12. The computer system of claim 11, wherein the processor-executable instructions, when executed by the processor, further configure the processor to:
generate a quality of result trajectory prediction based on the intermediate quality of results determined during each iteration of the logic synthesis optimization.

13. The computer system of claim 10, wherein the recipe recommendation model includes a graph encoder and a recipe encoder and the processor-executable instructions, when executed by the processor, further configure the processor to:
train the graph encoder and the recipe encoder to predict intermediate quality of results based on a set of training data generated during previous logic synthesis optimizations.

14. The computer system of claim 13, wherein the training includes self-supervised learning.

15. The computer system of claim 10, wherein the processor-executable instructions, when executed by the processor, further configure the processor to:
provide a plug-in to a software module associated with electronic design automation, the plug-in configured to generate the recommended recipe for each circuit based on the quality of result determined during logic synthesis optimization in response to detection of a trigger condition.

16. The computer system of claim 15, wherein the trigger condition includes selection of an interface element presented within the software module associated with electronic design automation.

17. The computer system of claim 10, wherein the quality of result includes at least one of performance, area, power consumption, yield and reliability.

18. The computer system of claim 10, wherein the processor-executable instructions, when executed by the processor, further configure the processor to:
engage an And-Inverter Graph (AIG) encoder to model each circuit as an AIG.

19. A non-transitory computer readable storage medium comprising processor-executable instructions which, when executed, configure a processor to:
engage a trained recipe recommendation module to:
load a plurality of circuits into a circuit data loader;
separately load a plurality of recipes into a recipe data loader; and
generate a recommended recipe for each circuit based on at least one quality of result determined during logic synthesis optimization.

20. The non-transitory computer readable storage medium of claim 19, wherein the processor-executable instructions, when executed by the processor, further configure the processor to:
determine an intermediate quality of result during each iteration of the logic synthesis optimization.
